(19) United States
(12) Patent Application Publication
(10) Pub. No.: US 2011/0198117 A1
(43) Pub. Date: Aug. 18, 2011

(54) LAMINATE AND PROCESS FOR PRODUCING THE LAMINATE

(75) Inventors: Mitsuhiro Watanabe, Yokosuka-shi (JP); Hideo Honma, Yokosuka-shi (JP); Mitsushi Tada, Tokyo (JP); Takashi Iga, Tokyo (JP); Naoki Tanahashi, Tokyo (JP)

(73) Assignees: Kanto Gakuin University Surface Engineering Research Institute, Yokosuka-shi, Kanagawa (JP); Kanto Kasei Co., Ltd., Yokosuka-shi, Kanagawa (JP); Zeon Corporation, Tokyo (JP)

(21) Appl. No.: 13/061,034

(22) PCT Filed: Aug. 20, 2009
(86) PCT No.: PCT/JP2009/064562

§ 371 Date: Apr. 29, 2011

(30) Foreign Application Priority Data
Aug. 25, 2008 (JP) 2008-215232
Mar. 27, 2009 (JP) 2009-078331

(51) Int. Cl. H05K 1/03; B32B 15/08; C23C 14/02; B05D 5/12; H05K 3/06

(52) U.S. Cl. 174/268; 428/461; 427/533; 427/534

(57) ABSTRACT

A laminate including a resin layer and a metal layer, the resin layer being obtained by modifying at least part of the surface of a resin film including a thermoplastic cyclic olefin resin by ionizing irradiation, and the metal layer being formed on the modified area of the surface of the resin film by plating, a method of producing the same, and an electronic circuit board including a circuit formed by etching the metal layer of the laminate by photolithography, are disclosed. The laminate ensures that the insulating resin layer (flat surface) exhibits high adhesion to the conductor layer.

### TECHNICAL FIELD

The present invention relates to a laminate that may suitably be used for a high-frequency electronic circuit board or a low-resistance transparent conductive substrate, and a method of producing the same.

### BACKGROUND ART

A laminate (copper-clad laminate) produced by forming a metal layer on an insulating resin layer formed of an epoxy resin, a polyimide, or the like has been used as a material for an electronic circuit board used for a printed circuit board, an antenna substrate, or the like for processing a propagation signal. A laminate produced by bonding copper foil to a resin layer, a laminate produced by forming a metal layer on a resin layer by sputtering, a laminate produced by forming a metal layer on a resin layer by plating, and the like have been known. However, a resin material that has been used to form an insulating resin layer of a laminate has a high dielectric constant and a high dielectric loss, and shows a large change in dielectric constant at a high humidity due to a high water absorption. Therefore, the high-frequency signal propagation quality may change due to a change in humidity.

In order to solve the above problem, use of a fluororesin as the insulating resin has been proposed. Since the fluororesin has a low dielectric constant and a low water absorption, the fluororesin is preferable as a material for an insulating resin layer of a high-speed propagation substrate (board). However, since the fluororesin is nonpolar, and has poor adhesion to a metal layer, it is necessary to stack the resin layer on the metal layer after roughening the surface of the resin layer. Therefore, a skin effect occurs during high-frequency propagation. Moreover, since it is difficult to process the fluororesin, processing cost is required when using the fluororesin for a wiring board or the like.

A thermoplastic cyclic olefin resin has a low dielectric constant and a low water absorption almost equal to those of the fluororesin, and has attracted attention as an insulating material in recent years. However, since the thermoplastic cyclic olefin resin is also nonpolar, and has poor adhesion to a metal layer, it is necessary to oxidize the surface by a surface roughening process or a plasma process.

Adhesion to a metal layer may be improved without roughening the surface of a resin layer by forming a metal layer on an insulating resin layer using a dry vacuum process such as vapor deposition, sputtering, or ion plating. For example, Patent Document 1 discloses a laminated sheet produced by forming a conductor layer on a cyclic olefin resin through a deposited film. According to the method disclosed in Patent Document 1, since adhesion is improved by utilizing the deposited film, the metal layer can be stacked on the resin. However, since the deposited film must be formed, the process takes time. Moreover, since the film is normally deposited under high vacuum using a high vacuum system, the productivity decreases.

In Patent Document 2, a cyclic olefin resin is used to form an insulating resin layer, and the surface of the resin layer (sheet material) having a thickness of 3 mm is modified by applying ultraviolet rays in an oxygen-containing atmosphere, and then copper-plated. According to the method disclosed in Patent Document 2, a plating film can be formed on the resin layer formed using the cyclic olefin resin. However, when using the laminate disclosed in Patent Document 2 for an electrical circuit board, adhesion of the plating film to the flat surface (resin layer) may be insufficient. In particular, when using the laminate disclosed in Patent Document 2 for a flexible printed circuit board, the copper plating film may be removed due to bending.

### RELATED-ART DOCUMENT

### Patent Document

Patent Document 1: JP-A-2005-129601
Patent Document 2: JP-A-2008-94923

### DISCLOSURE OF THE INVENTION

### Problems to be Solved by the Invention

The present invention was conceived in view of the above situation. An object of the present invention is to provide a laminate in which an insulating resin layer (flat surface) exhibits high adhesion to a metal layer, and which may suitably be used as a material for a high-frequency electronic circuit board that implements excellent electrical properties in a high-frequency region, or a low-resistance conductive transparent substrate, and a method of producing the same.

### Means for Solving the Problems

The inventors of the present invention conducted extensive studies in order to achieve the above object. As a result, the inventors found that a laminate that includes a resin layer and a metal layer, the resin layer being obtained by modifying at least part of the surface of a resin film including a thermoplastic cyclic olefin resin by ionizing irradiation, and the metal layer being formed on the modified area of the surface of the resin film by plating, ensures that the insulating resin layer (flat surface) exhibits high adhesion to the metal layer, and may suitably be used as a material for a high-frequency electronic circuit board that implements excellent electrical properties in a high-frequency region, or a low-resistance conductive transparent substrate. This finding has led to the completion of the present invention.

According to a first aspect of the present invention, there is provided the following laminate (see (1) to (4)).

(1) A laminate including a resin layer and a metal layer, the resin layer being obtained by modifying at least part of the surface of a resin film including a thermoplastic cyclic olefin resin by ionizing irradiation, and the metal layer being formed on the modified area of the surface of the resin film by plating.
(2) The laminate according to (1), wherein the resin film has been obtained by molding the thermoplastic cyclic olefin resin by melt extrusion or melt pressing.
(3) The laminate according to (1) or (2), wherein the resin film has a volatile content of 0.3 wt % or less.
(4) The laminate according to any one of (1) to (3), wherein the surface of the resin film has an arithmetic average roughness (Ra) of 1 μm or less.

According to a second aspect of the present invention, there is provided the following method of producing a laminate (see (5) to (9)).

(5) A method of producing a laminate including molding a thermoplastic cyclic olefin resin by melt extrusion or melt pressing to obtain a resin film, modifying at least part of the surface of the resin film by ionizing irradiation, and forming a metal layer on the modified area of the surface of the resin film by plating.
(6) The method according to (5), wherein the modifying of at least part of the surface of the resin film includes washing the surface of the resin layer with an alkaline aqueous solution after ionizing irradiation.
(7) The method according to (6), wherein the forming of the metal layer includes forming a thin metal film layer by electroless plating.
(8) The method according to (7), wherein a metal salt is used as a plating catalyst for the electroless plating.
(9) The method according to (7) or (8), wherein a plating catalyst is adsorbed during the electroless plating by immersing the modified resin film in an aqueous solution of the plating catalyst.

According to a third aspect of the present invention, there is provided the following electronic circuit board (see (10) to (12)).

(10) An electronic circuit board including a circuit formed by etching the metal layer of the laminate according to any one of (1) to (4) by photolithography.
(11) An electronic circuit board including a circuit formed by the metal layer of the laminate according to any one of (1) to (4), the resin layer being obtained by modifying a given area of the surface of the resin film including the thermoplastic cyclic olefin resin in a pattern by ionizing irradiation, and the metal layer being formed on the modified area of the surface of the resin film by plating.
(12) The electronic circuit board according to (10) or (11), the electronic circuit board being a conductive substrate in which the circuit is formed parallel or in a mesh shape.

### Effects of the Invention

The present invention thus provides a laminate in which an insulating resin layer (flat surface) exhibits high adhesion to a metal layer, and which may suitably be used as a material for a high-frequency electronic circuit board that implements excellent electrical properties in a high-frequency region, or a low-resistance conductive transparent substrate, and a method of producing the same.

### BRIEF DESCRIPTION OF THE DRAWINGS

FIG. 1 is a view showing comb-shaped wires formed when evaluating the heat-humidity resistance reliability of a substrate provided with a copper wiring pattern (Examples 5 and 6 and Comparative Example 3).

FIG. 2 is a cross-sectional view showing a substrate formed when evaluating the thermal impact reliability of a substrate provided with a copper wiring pattern (Examples 11 and 12 and Comparative Example 5).

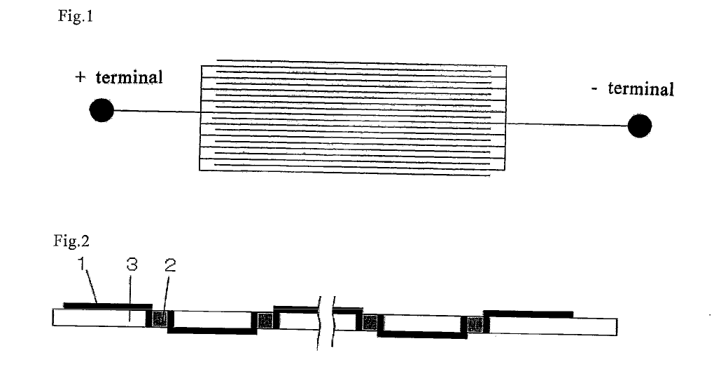

### EXPLANATION OF SYMBOLS

1: Copper plating wire (width: 50 μm, thickness: 10 μm)
2: Plated through-hole (diameter: 100 μm, wall plating thickness: 10 μm, 10 holes)
3: Insulating substrate (thickness: 100 μm)

### DESCRIPTION OF EXEMPLARY EMBODIMENTS

A laminate, a method of producing the same, and an electronic circuit board of the present invention are described in detail below.

### 1) Laminate and Method of Producing the Same

A laminate of the present invention includes a resin layer and a metal layer, the resin layer being obtained by modifying at least part of the surface of a resin film including a thermoplastic cyclic olefin resin by ionizing irradiation, and the metal layer being formed on the modified area of the surface of the resin film by plating.

### (Resin Layer)

The resin layer of the laminate of the present invention is formed of a resin film including a thermoplastic cyclic olefin resin, at least part of the surface of the resin film being modified by ionizing irradiation.

The term “thermoplastic cyclic olefin resin” used herein refers to a thermoplastic resin formed of a cyclic olefin homopolymer, a copolymer of a cyclic olefin and another monomer, or a hydrogenated product thereof.

Specific examples of the thermoplastic cyclic olefin resin include (i) a norbornene polymer, (ii) a monocyclic olefin addition polymer, (iii) a cyclic conjugated diene polymer, (iv) a vinylcycloalkane polymer, and the like.

### (i) Norbornene Polymer

The term “norbornene polymer” used herein refers to an addition polymer or a ring-opening polymer of a norbornene monomer, or a hydrogenated product thereof.

The term “norbornene monomer” used herein refers to a monomer having a norbornene ring structure. Examples of the norbornene monomer include bicyclo[2.2.1]-hept-2-ene, 5-ethylidene-bicyclo[2.2.1]-hept-2-ene, tricyclo[4.3.0.1^{2,5}]-deca-3,7-diene, tetracyclo[7.4.0.1^{10,13}.0^{2,7}]-trideca-2,4,6,11-tetraene, tetracyclo[4.4.0.1^{2,5}.1^{7,10}]-dodec-3-ene, 8-ethylidene-tetracyclo[4.4.0.1^{2,5}.1^{7,10}]-dodec-3-ene, 8-methoxycarbonyl-tetracyclo[4.4.0.1^{2,5}.1^{7,10}]-dodec-3-ene, 8-methoxycarbonyl-tetracyclo[4.4.0.1^{2,5}.1^{7,10}]-dodec-3-ene, and the like. These norbornene monomers may be used either individually or in combination.

The addition polymer of a norbornene monomer may be an addition copolymer of a norbornene monomer and a vinyl compound. The vinyl compound is not particularly limited insofar as the vinyl compound is copolymerizable with a norbornene monomer. Examples of the vinyl compound include ethylene or α-olefins having 2 to 20 carbon atoms, such as ethylene, propylene, and 1-hexene; cycloolefins such as cyclobutene, cyclopentene, cyclohexene, and cyclooctene; nonconjugated dienes such as 1,4-hexadiene and 1,7-octadiene; and the like. These vinyl compounds may be used either individually or in combination.

### (ii) Monocyclic Olefin Addition Polymer

Examples of the monocyclic olefin addition polymer include monocyclic olefin addition polymers such as cyclohexene, cycloheptene, and cyclooctene (see JP-A-64-66216, for example). The monocyclic olefin addition polymer may be an addition copolymer of a monocyclic olefin and the above vinyl compound.

(iii) Cyclic Conjugated Diene Polymer

Examples of the cyclic conjugated diene polymer include 1,2- or 1,4-addition polymers of a cyclic conjugated diene such as cyclopentadiene or cyclohexadiene, a hydrogenated product thereof, and the like (see JP-A-6-136057 and JP-A-7-258318, for example).

### (iv) Vinylcycloalkane Polymer

Examples of the vinylcycloalkane polymer include polymers of a vinylcyclohexene, a vinylcycloalkane such as vinylcyclohexane, and a hydrogenated product thereof (see JP-A-51-59989, for example); an aromatic ring-hydrogenated product of polymers of a vinyl aromatic compound such as styrene or α-methylstyrene (see JP-A-63-43910 and JP-A-64-1706, for example); and the like.

Among these thermoplastic cyclic olefin resins, the norbornene polymer is preferable from the viewpoint of excellent electrical properties and transparency, and a hydrogenated product of the ring-opening polymer of the norbornene monomer is more preferable.

The molecular weight of the thermoplastic cyclic olefin resin is appropriately selected depending on the application. The mechanical strength and the moldability are well-balanced when the thermoplastic cyclic olefin resin has a standard polystyrene-reduced weight average molecular weight, determined by gel permeation chromatography using a cyclohexane solution (or a toluene solution when the resin is not dissolved in cyclohexane), of 5000 or more, preferably 5000 to 500,000, still more preferably 10,000 to 300,000, and particularly preferably 25,000 to 200,000.

The thermoplastic cyclic olefin resin preferably has a glass transition temperature of 40 to 300° C., and more preferably 100 to 200° C. The glass transition temperature may be measured by differential scanning calorimetry (DSC).

The thermoplastic cyclic olefin resin preferably has a melt flow rate (280° C., load: 2.16 kg) of 1 to 100 g/10 min, and more preferably 1 to 60 g/10 min.

The thermoplastic cyclic olefin resin is molded into a resin film. The thermoplastic cyclic olefin resin is molded to have a planar shape (i.e., film or sheet). The surface size is appropriately selected depending on the application. The thickness of the resin film is normally 2 mm or less, preferably 1 mm or less, and more preferably 0.5 mm or less. If the thickness of the resin film is too large, the productivity may decrease. Moreover, the resin film may not exhibit sufficient flexibility when used for an electronic device substrate. The thickness of the resin film is normally 0.001 mm or more. If the thickness of the resin film is too small, the resin film may not exhibit sufficient strength when used for a substrate.

It is preferable that the resin film have high surface roughness in order to ensure that the resin film exhibits excellent adhesion to the metal layer. However, it is necessary to ensure that the resin film exhibits adhesion in a flat (smooth) state in order to improve the electrical properties (e.g., high-frequency propagation quality).

In order to ensure both adhesion and electrical properties, the arithmetic average roughness (Ra) of the surface of the resin film is normally 1 μm or less, preferably 0.5 μm or less, more preferably 0.1 μm or less, and particularly preferably 0.05 μm or less.

The resin film including the thermoplastic cyclic olefin resin may be formed by an arbitrary method. It is preferable to form the resin film by melt extrusion, melt pressing, or blow molding (more preferably melt extrusion or melt pressing, and particularly preferably melt extrusion). The resin film may be formed by injection molding. In this case, however, adhesion between the resulting resin layer and the metal layer may be insufficient. Specifically, when forming the resin film by injection molding, the resin may deteriorate due to a high temperature, a high speed, and high shear force, and may have a low molecular weight.

Moreover, fractionation may occur due to the molecular weight of the resin, so that a low-molecular-weight component having a low melt viscosity may enter a die and reach the surface of the die preliminary to a high-molecular-weight component. As a result, a low-molecular-weight component and a decomposition product may accumulate on the surface of the die (i.e., the surface area of the resin layer). It is conjectured that the mechanical strength may thus decrease around the contact surface with the metal layer, and adhesion may decrease. A decrease in adhesion can be suppressed by employing melt extrusion or melt pressing, so that a laminate in which the resin layer exhibits excellent adhesion to the metal layer can be obtained.

The resin layer may be formed by extrusion as follows, for example.

The cyclic olefin resin film used for the resin layer of the present invention is preferably formed by melting the thermoplastic cyclic olefin resin using an extruder, extruding the molten resin in the shape of a film from a die installed in the extruder, causing the extruded resin film to come in contact with at least one cooling drum, and taking up the resin film.

The die installed in the extruder is not particularly limited. Examples of the die include a T-die, a coat hanger die, a die used for an inflation method, and the like. Among these, it is preferable to use a T-die since a film having excellent surface flatness can be easily formed.

The length of the die lip is not particularly limited, but is preferably 20 cm or more, more preferably 50 cm or more, still more preferably 80 cm or more, and particularly preferably 1.3 m or more.

The width of the die lip is preferably 5 mm or more, more preferably 8 mm or more, and particularly preferably 10 mm or more.

The radius R of the edge of the die lip is preferably 0.05 mm or less, more preferably 0.01 mm or less, and particularly preferably 0.0015 mm or less.

The radius R of the edge refers to the radius of the chamfered corner area of the edge. The radius R of the edge of a T-die or the like that has been normally used is 0.2 to 0.3 mm. When using such a T-die, however, a molten resin or the like may adhere to the entrance of the lip during long-time continuous molding, so that the die line may be observed on the surface of the film. The surface flatness of the resulting film is improved as the radius R of the edge of the die lip decreases.

Examples of the material for the die include, but are not limited to, SCM steel, a stainless steel material (e.g., SUS), and the like.

The die lip may be produced by thermal spraying or plating hard chromium, chromium carbide, chromium nitride, titanium carbide, titanium carbonitride, titanium nitride, super-steel, a ceramic (tungsten carbide, aluminum oxide, or chromium oxide), or the like. Among these, it is preferable to use a ceramic (particularly preferably tungsten carbide).

The die lip suitably used for the present invention has a peel strength of 75 N or less, and preferably 50 N or less. When using a die lip having a peel strength within the above range, adhesion of a thermally decomposed product and a high-temperature melt of the molten cyclic olefin resin to the die lip can be prevented, so that the die line is rarely observed on the surface of the molded product.

The die used for the production method of the present invention may be produced by an arbitrary method. For example, it is preferable to grind the die lip by pressure machining using a diamond wheel.

It is preferable to apply a rust preventive to the die lip. Examples of the rust preventive applied to the die lip include volatile compounds such as nitrates, carboxylates, and carbonates of amines. Specific examples of the rust preventive include dicyclohexylammonium nitrate, diisopropyl ammonium nitrate, dicyclohexylammonium caprylate, cyclohexylammonium carbamate, cyclohexylamine carbonate, and the like.

In the production method of the present invention, (a) the rust preventive that adheres to the die lip may be removed using a solvent, or (b) the process including extruding the resin in the shape of a film from the die, causing the extruded cyclic olefin resin film to come in contact with at least one cooling drum, and taking up the resin film may be performed at an atmospheric pressure of 50 kPa or less in order to achieve a more excellent effect, for example.

When employing melt extrusion utilizing a T-die, the thermoplastic cyclic olefin resin is preferably melted in an extruder having a T-die at a temperature higher than the glass transition temperature of the resin by 80 to 180° C., and more preferably 100 to 150° C. If the resin is melted in an extruder at too low a temperature, the flowability of the resin may be insufficient. If the resin is melted in an extruder at too high a temperature, the resin may deteriorate.

The thermoplastic cyclic olefin resin film extruded through the opening of the die may be caused to come in contact with the cooling drum by an arbitrary method, such as an air knife method, a vacuum box method, or an electrostatic method.

The number of cooling drums is not particularly limited, but is normally two or more. The cooling drums may be disposed by an arbitrary method. For example, the cooling drums may be disposed linearly, or may be disposed in the shape of the letter Z or L. The thermoplastic cyclic olefin resin film extruded through the opening of the die may be passed through the cooling drums by an arbitrary method.

The state of adhesion of the extruded cyclic olefin resin film to the cooling drum changes depending on the temperature of the cooling drum. The adhesion state is improved by increasing the temperature of the cooling drum. However, the thermoplastic cyclic olefin resin film may be wound around the cooling drum without being removed from the cooling drum if the temperature of the cooling drum is increased to a large extent. When the glass transition temperature of the cyclic olefin resin extruded from the die is referred to as Tg (° C.), the temperature of the cooling drum is preferably set to (Tg+30)° C. or less, and more preferably (Tg−5) to (Tg−45)° C. This makes it possible to more reliably prevent slippage, breakage, and the like.

It is preferable to melt the thermoplastic cyclic olefin resin in the extruder, and pass the molten thermoplastic cyclic olefin resin through a gear pump or a filter before extruding the thermoplastic cyclic olefin resin from the die installed in the extruder. A uniform amount of resin can be extruded by utilizing a gear pump, so that a variation in thickness can be reduced. Foreign matter can be removed from the resin by utilizing a filter, so that a thermoplastic cyclic olefin resin film that has no defects and has an excellent appearance can be obtained.

It is preferable that the resin layer used for the present invention have a low volatile content. The volatile content in the resin layer is preferably 0.3 wt % or less, and more preferably 0.1 wt % or less. If the volatile content in the resin layer is within the above range, foaming and defects of the resin layer, and a decrease in adhesion to the metal layer can be prevented, for example.

The volatile content in the resin layer may be reduced by (α) reducing the volatile content in the resin or an additive, or (β) preliminary drying of the resin before forming the resin layer, for example.

For example, the resin may be preliminarily dried by pelletizing the resin, and drying the resulting pellets using a hot-blast dryer or the like. The drying temperature is preferably 100° C. or more, and the drying time is preferably 2 hours or more. The volatile content in the resin layer can be reduced by preliminary drying of the resin.

The water absorption of the resin layer is preferably low from the viewpoint of environment resistance, insulation reliability, and propagation quality. The water absorption of the resin layer is preferably 0.5 wt % or less, and more preferably 0.1 wt % or less. The water absorption of the resin layer may be measured in accordance with JIS K 7209.

It is preferable that the resin layer be transparent. In particular, transparency is required when the resin layer is used for a transparent conductive substrate, a printed circuit board, or an antenna substrate. When the resin layer is used for applications that do not require transparency, the resin layer may be colored, or the transparency of the resin layer may be impaired due to convenience of production, an additive added to improve performance, or the like.

The term “transparent” used herein means that the resin layer has a high light transmittance in the visible region, or has a high light transmittance in the visible to near infrared region. It is preferable that the resin layer have a light transmittance at a wavelength of 780 nm of 70% or more, and more preferably 80% or more.

The resin layer used for the present invention may appropriately include additives such as a coloring agent (e.g., pigment and dye), a fluorescent whitening agent, a dispersant, a thermal stabilizer, a light stabilizer, a UV absorber, an antistatic agent, an antioxidant, a lubricant, and a flame retardant.

When the resin layer is used for a long time of 10 years or more (e.g., large liquid crystal display), or used in an environment in which the resin layer is exposed to sunlight outdoors (e.g., solar cell substrate), it is preferable that the resin layer include an antioxidant and a UV absorber in order to improve weatherability.

As the antioxidant, an antioxidant having a molecular weight of 700 or more is preferably used. If the molecular weight of the antioxidant is too low, the antioxidant may be eluted from the molded product. Specific examples of the antioxidant include phenol antioxidants such as octadecyl-3-(3,5-di-t-butyl-4-hydroxyphenyl)propionate, tetrakis[methylene-3-(3′,5′-di-t-butyl-4′-hydroxyphenyl)propionate]methane, and pentaerythrityl-tetrakis[3-(3,5-di-tert-butyl-4-hydroxyphenyl)propionate]; phosphorus-containing antioxidants such as triphenyl phosphite, tris(cyclohexylphenyl) phosphite, and 9,10-dihydro-9-oxa-10-phosphaphenanthrene; sulfur-containing antioxidants such as dimyristyl-3,3′-thiodipropionate, distearyl-3,3′-thiodipropionate, laurylstearyl-3,3′-thiodipropionate, and pentaerythritol-tetrakis(β-lauryl-thiopropionate); and the like. These antioxidants may be used either individually or in combination.

Among these, the phenol antioxidants are preferable.

Examples of the UV absorber include oxybenzophenone compounds, benzotriazole compounds, salicylate compounds, benzophenone UV absorbers, benzotriazole UV absorbers, acrylonitrile UV absorbers, triazine compounds, nickel complex salt compounds, inorganic powders, and the like.

It is preferable to use 2,2′-methylenebis(4-(1,1,3,3-tetramethylbutyl)-6-(2H-benzotriazol-2-yl)phenol), 2-(2′-hydroxy-3′-tert-butyl-5′-methylphenyl)-5-chlorobenzotriazole, 2,4-di-tert-butyl-6-(5-chlorobenzotriazol-2-yl)phenol, 2,2′-dihydroxy-4,4′-dimethoxybenzophenone, 2,2′,4,4′-tetrahydroxy benzophenone, or the like. Among these, 2,2′-methylenebis(4-(1,1,3,3-tetramethylbutyl)-6-(2H-benzotriazol-2-yl)phenol) is particularly preferable.

The UV absorber may be layered on the side of the resin layer opposite to the interface with the metal layer as a coating material or a laminate material that includes the UV absorber and a resin (e.g., curable acrylic resin, epoxy resin, urethane resin, or silicone resin).

The antioxidant or the UV absorber is normally used in an amount of 0.001 to 5 parts by weight, and preferably 0.01 to 1.0 parts by weight, based on 100 parts by weight of the resin. If the amount of the antioxidant is too small, a sufficient effect may not be obtained. If the amount of the antioxidant is too large, adhesion to the metal layer may decrease, or the antioxidant or the UV absorber may be eluted.

A lubricant may be used to improve the film-formability, winding capability, and flexibility. Examples of the lubricant include inorganic particles such as silicon dioxide, titanium dioxide, magnesium oxide, calcium carbonate, magnesium carbonate, barium sulfate, and strontium sulfate, and organic particles such as polymethyl acrylate, polymethyl methacrylate, polyacrylonitrile, polystyrene, cellulose acetate, and cellulose acetate propionate. The lubricant is preferably added in an amount of 1 wt % or less, and more preferably 0.5 wt % or less, in order to maintain the surface roughness and the mechanical strength.

When transparency is not necessary, a rubber-like elastic polymer or elastic particles formed of a rubber-like elastic polymer may be mixed into the resin layer in order to improve the flexibility. Examples of the rubber-like elastic body include, but are not limited to, an acrylic rubber, a diene rubber that includes butadiene or isoprene as the main component, a hydrogenated product thereof, an ethylene-vinyl acetate copolymer, an ethylene-propylene rubber, a butyl rubber, a silicone rubber, a fluororubber, and the like.

When it is necessary to achieve high-frequency propagation at 1 GHz or more, the rubber-like elastic body is normally added in an amount of 10 wt % or less, preferably 5 wt % or less, and more preferably 1 wt % or less. If the amount of the rubber-like elastic body is too large, the phase of the rubber-like elastic body may be partially removed when treating the surface of the resin layer, so that a variation in performance may occur across the resulting circuit board.

When the laminate is used for a circuit board of a flexible printed wiring board used for a flexible movable section of a mobile phone, a hard disk drive, or the like, the rubber-like elastic body may be added in an amount of 10 wt % or more in order to improve the durability of the flexible movable section.

If the amount of the rubber-like elastic body is large, it is difficult to uniformly disperse the rubber-like elastic body in the material when using injection molding since the molten resin is injected at a high temperature and high pressure. Therefore, it is preferable to form the resin layer by extrusion so that the rubber-like elastic body can be uniformly dispersed.

A flame retardant may be mixed into the resin layer in order to prevent ignition and combustion due to dielectric breakdown caused by overcurrent or the like. A commercially available flame retardant may be used. It is preferable to use a phosphorus-based flame retardant, a metal oxide-based flame retardant, or an inorganic oxide-based flame retardant. The amount of the flame retardant may be appropriately determined. The flame retardant is preferably added in an amount of 30 wt % or less, more preferably 20 wt % or less, and still more preferably 10 wt % or less, in order to maintain the electrical properties.

The laminate may be required to exhibit surface hardness or antireflective properties when the laminate is used for a conductive substrate of a solar cell, a flat panel display, a touch panel, or the like. In this case, the surface of the resin layer opposite to the interface with the metal layer may be coated or textured.

### (Surface Modification)

The resin layer used in the present invention is obtained by modifying at least part of the surface of the above resin film by ionizing irradiation.

The term “ionizing radiation” used herein refers to electromagnetic waves or charged particle rays having an energy quantum that can polymerize or crosslink molecules. Examples of the ionizing radiation include visible rays, ultraviolet rays (e.g., near ultraviolet rays and vacuum ultraviolet rays), X-rays, electron beams, ion lines, and the like. Ultraviolet rays or electron beams are normally used as the ionizing radiation. It is preferable to use ultraviolet rays.

As the UV source, a mercury lamp (e.g., supervoltage mercury lamp, high-voltage mercury lamp, or low-voltage mercury lamp), a carbon-arc lamp, a black light fluorescent lamp, a metal halide lamp, or the like may be used. Among these, the mercury lamp is preferable. The wavelength band of ultraviolet rays may be 180 to 400 nm.

The method of modifying the surface of the resin film is not particularly limited insofar as ionizing irradiation is used, but preferably includes the following steps A to C. The steps A to C are described below.

In the step A, contaminants (e.g., oil and fats) adhering to the surface of the resin film are removed. For example, laminated paper or the like may be bonded to the surface of the resin film as a protective material. In this case, oil and fats contained in the laminated paper adhere to the sheet material. If adhesion of contaminants is minor, a cleaning (degreasing) process using an alkaline solution having a caustic soda concentration of about 50 g/l is used, for example. It is also possible to use ultrasonic cleaning, plasma cleaning, or the like.

Note that the step A is not indispensable as a preprocess for the step B, but aims at reliably utilizing the irradiation effect of ultraviolet rays. When the amount of contaminants is small, for example, a sufficient effect may be obtained even if the step A is performed after the step B.

In the step B, ionizing radiation is applied to the resin layer. The dominant wavelength of ionizing radiation used in the step B is preferably 180 to 400 nm. The intensity of ionizing radiation at the surface of the resin layer is preferably 1 to 500 mW/cm².

Ionizing irradiation is preferably performed in an oxygen-containing atmosphere. Ionizing irradiation is used to modify the resin layer in order to convert the C—H bonds of the resin layer into an —OH group and/or a —C═O group by utilizing the energy of ionizing radiation applied in an oxygen-containing atmosphere. This increases the chemical bonding force between the resin layer and a plating catalyst or the metal layer.

It is preferable to perform the step B in air (i.e., oxygen-containing atmosphere) due to convenience. The C—H bonds can be easily converted into an —OH group and/or a —C═O group by applying ultraviolet rays in an oxygen-containing atmosphere. A structure including nitrogen and the like may be obtained by performing the step B in a nitrogen-containing atmosphere (e.g., nitrogen atmosphere or ammonia atmosphere).

The lower limit of the wavelength of ionizing radiation is preferably 180 nm Note that the modification effect can also be obtained at a wavelength equal to or less than 180 nm The above lower limit refers to the lower limit of a wavelength that may normally be used. A more advantageous effect may be obtained using a light source that emits light having a shorter wavelength. The upper limit of the wavelength of ionizing radiation is preferably 400 nm. The light transmittance of the insulating resin layer may increase when using ionizing radiation having a wavelength of longer than 400 nm, so that it may be difficult to obtain a modification effect. The wavelength range of ionizing radiation is more preferably 180 to 300 nm, and still more preferably 180 to 280 nm.

For example, when using a mercury lamp as the ionizing radiation source, a plurality of ionizing radiation wavelengths are observed, and the dominant wavelengths are 253.7 nm and 184.9 nm. In this case, ionizing radiation having a wavelength of 184.9 nm easily ozonizes oxygen in air present between the resin layer and the light source, so that surface modification of the resin layer is promoted. This makes it possible to obtain a laminate in which the resin layer exhibits high adhesion to the metal layer.

The intensity of ionizing radiation at the surface of the resin layer may be determined (selected) taking account of the relationship with the irradiation time. If the intensity of ionizing radiation is less than 1 mW/cm², the modification process may take time, so that the production efficiency may decrease. If the intensity of ionizing radiation exceeds 500 mW/cm², the inside of the resin layer may also be modified in addition to the surface of the resin layer, and it may be difficult to control such a situation. As a result, the entire insulating resin layer may become fragile. Therefore, when using an ionizing radiation source that achieves an intensity that exceeds the above upper limit, optimum irradiation conditions and an optimum apparatus are selected (set) by changing the irradiation time and the like, and it is necessary to employ a very short irradiation time. When using a mercury lamp as the ionizing radiation source, the intensity of ionizing radiation having a wavelength of 184.9 nm at the surface of the resin layer is preferably 1 to 20 mW/cm², and particularly 5 to 10 mW/cm².

When using a normal low-pressure mercury lamp, the irradiation time of ionizing radiation in the step B is preferably 10 seconds to 15 minutes, and more preferably 30 seconds to 10 minutes. The surface modification level and the depth from the surface to which the modification effect reaches can be controlled by changing the intensity of ionizing radiation and the irradiation time.

The temperature of the surface of the resin layer during ionizing irradiation is preferably 5 to 100° C., and more preferably 10 to 60° C. If the temperature of the surface of the resin layer is too low, the modification process may take time, so that the production efficiency may decrease. If the temperature of the surface of the resin layer is too high, adhesion to the metal layer may decrease. The temperature of the surface of the resin layer may be adjusted within the above range by cooling the resin layer by cooling a stage of an ionizing irradiation apparatus on which the resin layer is placed, or cooling air present in the irradiation atmosphere, for example. If the resin layer is excessively cooled, water in air may condense. Therefore, it is preferable to cool the resin layer to such an extent that condensation does not occur, or use dried air.

The atmosphere between the resin layer and the radiation source during irradiation is not particularly limited, but may be a vacuum atmosphere, a nitrogen atmosphere, or the like. It is preferable to use an oxygen-containing atmosphere such as a dry air atmosphere. If at least a small amount of oxygen is present, a laminate in which the resin layer exhibits high adhesion to the metal layer can be obtained.

In the step C, the resin layer obtained by the step B is washed (cleaned). It is preferable to wash (clean) the surface of the resin layer subjected to ionizing irradiation using an alkaline solution or the like, and then wash the surface of the resin layer with water. Contaminants (e.g., dust and organic substance) and a substance adhering to the surface of the resin layer can be removed from the surface of the resin layer before a step I (described later) by performing the step C. Moreover, a low-molecular-weight component produced on the surface of the resin layer during the step B can be removed, so that a microscopic etched shape can be formed. Therefore, adhesion between the resin layer and the metal layer can be improved due to an anchor effect.

The washing method used in the step C is not particularly limited. It is preferable to immerse the resin layer in a washing solvent. It is preferable to use an acidic or alkaline aqueous solution or an organic solvent as the washing solvent. It is more preferable to use an alkaline aqueous solution as the washing solvent.

As the acidic aqueous solution, a hydrochloric acid aqueous solution, a sulfuric acid aqueous solution, a nitric acid aqueous solution, an acetic acid aqueous solution, a citric acid aqueous solution, or the like may be used. The pH of the acidic aqueous solution is preferably 6 or less.

As the alkaline aqueous solution, a sodium hydroxide aqueous solution, a potassium hydroxide aqueous solution, an ammonia aqueous solution, or the like may be used. The pH of the alkaline aqueous solution is preferably 8 or more.

Examples of the organic solvent include alcohols, ketones, hydrocarbons, and the like.

A mixture of the organic solvent (e.g., alcohol or ketone) and water may also be used to wash the resin layer. Note that a hydrocarbon solvent may serve as a good solvent for the resin layer. Therefore, it is preferable to dilute a hydrocarbon solvent with a poor solvent (e.g., alcohol) so that the resin layer is not significantly deformed due to the solvent.

When using an aqueous solution, the immersion temperature is preferably 5 to 90° C., more preferably 10 to 70° C., and particularly preferably 15 to 50° C. If the immersion temperature is too low, the cleaning/removal operation may be insufficient. If the immersion temperature is too high, handling may be difficult. When using the organic solvent, the immersion temperature is preferably 0 to 60° C. If the immersion temperature is too low, the cleaning/removal operation may be insufficient. If the immersion temperature is too high, it may be troublesome to manage the liquid due to volatilization, and the working environment may be impaired.

The immersion time is preferably 10 seconds to 10 minutes, and more preferably 30 seconds to 5 minutes. If the immersion time is too short, the cleaning effect may become non-uniform. If the immersion time is too long, the productivity may decrease.

After the step C, it is preferable to wash the resin layer with purified water, ion-exchanged water, or the like. The resin layer may not be dried after washing if a metal film-forming step is immediately performed. When forming the metal film a few days later, for example, the effects of surface non-uniformity can be reduced by drying the resin layer.

The resin layer thus obtained has been modified by appropriately setting the ionizing irradiation conditions corresponding to properties required for the application. An —OH group and a —C═O group are formed on the modified surface of the resin layer. The —OH group and the —C═O group improve chemical adhesion. The surface roughness (Ra) after modification is preferably 1 μm or more from the viewpoint of an improvement in adhesion. It is preferable to reduce the surface roughness after modification in order to improve the propagation properties and the like.

It is preferable to then subject the resin layer to a conditioning treatment. For example, the resin layer may be immersed in a commercially available conditioner (aqueous solution that contains a surfactant and the like). The conditioning treatment allows metal atoms to be uniformly adsorbed on the resin layer utilizing a plating catalyst or electroless plating, so that adhesion between the thin metal film layer and the resin layer can be improved.

The conditioning treatment is preferably performed at a temperature of 5 to 90° C., and more preferably 10 to 70° C. If the temperature is too low, the conditioning treatment may become non-uniform. If the temperature is too high, handling may be inconvenient.

The conditioning treatment is preferably performed for 10 seconds to 10 minutes, and more preferably 30 seconds to 5 minutes. If the treatment time is too short, the conditioning treatment may become non-uniform. If the treatment time is too long, the productivity may decrease.

### (Metal Layer)

In the laminate of the present invention, the metal layer is formed on the modified surface of the resin film by plating. The metal layer may be formed by an arbitrary plating method. It is preferable to use a method that includes forming a thin metal film layer on the surface-modified resin layer (step I), and then forming a metal film on the surface of the resin layer by subjecting the thin metal film layer to electrolytic plating (step II).

In the step I, the thin metal film layer is formed on the surface-modified resin layer. When forming a metal layer, excellent productivity and excellent quality are normally achieved by employing electrolytic plating. When forming a metal layer on a non-conductor, however, a metal layer that supplies electricity necessary for electrolytic plating is not initially present. Therefore, it is preferable to first form a thin metal layer on the surface of the surface-modified resin layer to obtain a thin metal film layer. It is possible to form a thin metal layer having the desired thickness by high-speed electroless plating if the desired quality can be achieved.

In the step I, it is preferable to use electroless plating. An —OH group and a —C═O group are formed on the surface of the resin layer according to one embodiment of the present invention. Therefore, a deposited metal component and the resin layer are easily chemically bonded using a liquid phase reaction. Moreover, a metal layer can be formed by depositing a metal component within a narrow area due to entrance of the liquid in the etched shape. Therefore, adhesion between the resin layer and the metal layer can be improved due to a microscopic anchor effect.

When forming the thin metal film layer by electroless plating, a plating catalyst is normally adsorbed on the resin layer before forming the thin metal film layer on the surface of the resin layer. The plating catalyst may be adsorbed on the resin layer by an arbitrary method. For example, the resin layer may be immersed in a liquid prepared by dissolving or dispersing the plating catalyst in water or an organic solvent (e.g., alcohol or chloroform) at a concentration of 0.001 to 10 wt % (the liquid may optionally contain an acid, an alkali, a complexing agent, a reducing agent, or the like), and the metal that forms the plating catalyst may be reduced. It is preferable to immerse the resin layer in an aqueous solution of the plating catalyst from the viewpoint of safety and waste treatment. The resin layer may be pre-dipped before adsorbing the plating catalyst on the resin layer. The resin layer may be pre-dipped by immersing the resin layer in a known pre-dipping liquid. The catalyst bonding (application) properties can be improved by pre-dipping.

Examples of the catalyst include compounds of metals such as copper, silver, palladium, zinc, and cobalt. Specific examples of the catalyst include salts and complexes of these metals. It is preferable to use a metal salt. The plating catalyst can be adsorbed on the resin layer at a molecular level by utilizing a metal salt as the plating catalyst. Therefore, a laminate in which the resin layer exhibits high adhesion to the metal layer can be obtained even if the surface of the resin layer is flat.

Two or more metal compounds may be used as the plating catalyst either simultaneously or successively. For example, the catalyst activity can be increased by adding a tin compound to a metal salt aqueous solution. The resin layer may be immersed in an aqueous solution of a tin compound, washed with water, and then immersed in an aqueous solution of another metal compound.

The plating catalyst is preferably adsorbed at a temperature of 5 to 90° C., and more preferably 10 to 70° C. If the temperature is too low, the adsorption treatment may be insufficient. If the temperature is too high, handling may be inconvenient.

The plating catalyst adsorption time is preferably 10 seconds to 10 minutes, and more preferably 30 seconds to 5 minutes. If the adsorption time is too short, the adsorption treatment may be insufficient. If the adsorption time is too long, the productivity may decrease.

When performing electroless plating, a high-speed electroless plating bath may be used, and the resin layer may be plated to the desired thickness. In order to stabilize adhesion between the deposited electroless plating layer and the surface-modified resin layer, it is preferable to use a formalin-containing electroless plating bath or an electroless plating bath using hypophosphorous acid having a low deposition rate as a reducing agent. In this case, the accuracy of deposition of the metal component on a narrow area having a minute elevation/depression shape can be improved, so that excellent adhesion between the electroless plating layer and the resin layer can be obtained.

Electroless copper plating, electroless nickel plating, electroless tin plating, electroless gold plating, or the like may be used as the above electroless plating.

The thin metal film layer may also be formed by physical vapor deposition.

The thickness of the thin metal film layer is preferably 0.1 to 3 μm. If the thickness of the thin metal film layer is less than 0.1 μm, the thickness may be non-uniform, so that a stable conduction state may not be obtained during electroplating. If the thickness of the thin metal film layer exceeds 3 μm, the deposited metal surface may become coarse, so that the surface of the electrolytic plating layer formed by the subsequent electrolytic plating may also become coarse. It is more preferable that the thin metal film layer have a thickness of 0.2 to 2 μm in order to obtain a thin metal film layer that exhibits excellent flatness and thickness uniformity and does not adversely affect the subsequent electrolytic plating.

In the step II, the thin metal film layer is subjected to electrolytic plating to form a metal film on the surface of the resin layer. This electrolytic plating is not particularly limited. The resulting electrolytic plating layer may have an arbitrary thickness. An arbitrary material and an arbitrary thickness may be selected depending on the application of the resulting laminate. This also applies to the material for the electrolytic plating layer.

For example, various types of electrolytic plating such as copper plating, nickel plating, tin plating, zinc plating, iron plating, copper-zinc alloy plating, nickel-cobalt alloy plating, and nickel-zinc alloy plating may be used. The material of the electrolytic plating layer formed by electrolytic plating and the metal component that forms the thin metal film layer may be either the same or different. The combination of the materials may be arbitrarily selected depending on the application of the laminate, the desired adhesion between the surface of the resin layer and the metal layer, and the like.

The thickness of the metal layer included in the laminate of the present invention is selected depending on the application of the laminate, but is normally 0.1 to 100 μm, and preferably 0.3 to 50 μm. When using the laminate of the present invention for an electronic circuit board, the thickness of the metal layer is more preferably 1 to 30 μm. If the thickness of the metal layer is less than the above range, a signal loss may occur due to an increase in electrical resistance, although the thickness of the resulting electronic instrument can be reduced. If the thickness of the metal layer exceeds the above range, the reliability, the quality, and the heat dissipation capability of a circuit board that uses a high current can be ensured, but the plating process may take time, so that the productivity may decrease.

In the laminate of the present invention, it is preferable that the surface of the resin layer after dissolving and removing the metal layer have an arithmetic average roughness (Ra) of 5 μm or less. The surface roughness is selected depending on the application. Since chemical adhesion effectively occurs as a result of using the modification method that applies ultraviolet rays in an oxygen-containing atmosphere, it is unnecessary to roughen the surface to a large extent. It is preferable to employ a very low profile level required for an adhesive surface of copper foil used for normal printed wiring boards. The surface roughness (Ra) is more preferably 1 μm or less when the laminate is used for a printed wiring board in high-frequency applications.

### 2) Electronic Circuit Board

The laminate of the present invention is preferably an electronic circuit board in which the metal layer forms a circuit.

The circuit may be formed by an arbitrary method. The circuit may be formed by a subtractive process or a semi-additive process.

The subtractive process or the semi-additive process removes part of the metal layer by wet etching through a resist mask patterned by photolithography to form a circuit.

When using a normal subtractive process, the surface of the laminate is finished, and a dry film photoresist is bonded to the laminate. The resist is exposed using an exposure system utilizing a photomask having a circuit pattern, and developed to form a mask pattern. An etching process is then performed using an etchant, and the resist is removed.

When using a normal semi-additive process, a resist pattern is formed in the same manner as in the subtractive process. The space formed by the resist pattern is plated by electrolytic plating, and the resist is removed. The metal layer that has been present under the resist is then removed by etching.

The subtractive process is normally used when the wiring pitch is 30 μm or more, the semi-additive process is used when it is 30 μm or less.

When modifying the surface of the resin layer by ionizing irradiation, ionizing radiation may be applied using a photomask having a circuit pattern, and a plating layer may be selectively formed only in the modified area to directly form a circuit pattern of a metal layer on the insulating resin layer.

In this case, since a wire can be formed without using a photoresist, the production process can be significantly simplified. Moreover, the metal material can be saved.

### (Electronic Circuit Board)

It is preferable that the electronic circuit board of the present invention be a conductive substrate in which the circuit is formed parallel or in a mesh shape.

A substrate that is transparent and has a low sheet resistance can be produced by forming wires parallel or in a mesh shape. Therefore, a substrate having a low resistance can be obtained as compared with a transparent conductive film substrate using ITO. Moreover, the steam barrier properties and the low water absorption of the thermoplastic cyclic olefin resin can be directly utilized.

The expression “parallel or in a mesh shape” refers to a pattern in which wires having a given width (e.g., 20 μm) are disposed parallel or in a grid arrangement at given intervals (e.g., 200 μm). The parallel or mesh pattern need not be parallel to the substrate (i.e., may be formed in an arbitrary direction).

The grid shape of the mesh pattern may be a square, a rectangle, a diamond, or a parallelogram. The interval between the wires is preferably 0.01 to 2 mm, and more preferably 0.05 to 1 mm, so that light is not blocked, and the resistance is reduced. The width of the wires is preferably 1 mm or less, and more preferably 0.5 mm or less.

The electronic circuit board produced using the laminate of the present invention may be used for arbitrary applications. A printed circuit board such as a rigid printed circuit board, a flexible printed circuit board, or a rigid flexible printed circuit board may be produced using the laminate of the present invention. In particular, the laminate of the present invention is preferably used as a build-up layer of a rigid printed circuit board or a flexible printed circuit board. When using the laminate of the present invention for a film-shaped antenna substrate, the antenna substrate can be bonded to the display or the housing of a mobile phone, for example. This enhances the range of application.

### Examples

The present invention is further described below. Note that the present invention is not limited to the following examples. In the examples, the unit “parts” refers to “parts by weight”, and the unit “%” refers to “wt %” unless otherwise indicated.

### (Measurement of Properties)

### (Glass Transition Temperature (Tg))

The glass transition temperature of the cyclic olefin resin used to form the resin layer was measured using a differential scanning calorimeter (DSC) when heating the sample to 200° C., cooling the sample to room temperature at a cooling rate of −10° C./min, and then heating the sample at a temperature rise rate of 10° C./min

### (Thickness)

The thickness of the resin layer and the metal layer was measured using a micro gauge.

### (Surface Roughness (Ra))

The average surface roughness (Ra) was evaluated by determining the centerline average roughness Ra (JIS B 0601-2001) based on the measured values at five points in a square area (20×20 μm) using a non-contact optical surface shape measuring device (color laser microscope “VK-8500” manufactured by Keyence Corp.).

### (Volatile Content)

The volatile content was measured by thermogravimetry (TGA) in a nitrogen atmosphere as a heating loss from 30 to 350° C. at a temperature rise rate of 10° C./min.

### (Peel Strength)

The laminate was immobilized, and part of the metal layer and the resin layer was physically peeled off, and pulled at 90° using a tensile tester to measure the plating peel strength.

### (Light Transmittance)

The light transmittance at a wavelength of 780 nm was measured using a UV spectrophotometer (“V-570” manufactured by JASCO Corporation).

### (Sheet Resistance)

The sheet resistance was measured by a four-terminal four-probe method in accordance with JIS K 7194.

### Formation of Resin Layer

### Production Example 1

Pellets of a thermoplastic cyclic olefin resin (“Zeonor 1420” manufactured by Zeon Corporation, glass transition temperature (Tg): 136° C.) were dried at 100° C. for 4 hours using a hot-blast dryer through which air was circulated. The pellets were extruded at 260° C. using a single-screw extruder (50 mm) provided with a leaf-disc polymer filter (filtration accuracy: 30 μm) and a T-die. The extruded sheet-shaped thermoplastic cyclic olefin resin was passed (cooled) through three cooling drums (diameter: 250 mm, drum temperature: 120° C., take-up speed: 0.35 msec) to obtain a transparent resin film. The thickness of the film was 100±2 μm. The volatile content was 0.1% or less. The surface roughness (Ra) of the film was 0.05 μm or less. Surface defects (e.g., die line, fish eye, foreign matter, dent, projection, and scratches) were not observed with the naked eye when applying light.

### Production Example 2

A transparent resin film was obtained in the same manner as in Production Example 1, except for using pellets of another thermoplastic cyclic olefin resin (“Zeonor 1600” manufactured by Zeon Corporation, glass transition temperature (Tg): 160° C.), and changing the extrusion temperature to 280° C. The thickness of the film was 100±2 μm. The volatile content was 0.1% or less. The surface roughness (Ra) of the film was 0.05 μm or less. Surface defects (e.g., die line, fish eye, foreign matter, dent, projection, and scratches) were not observed with the naked eye when applying light.

### Comparative Production Example 1

Pellets of a cyclic olefin resin (“Zeonor 1420” manufactured by Zeon Corporation, glass transition temperature (Tg): 136° C.) were dried at 100° C. for 4 hours using a hot-blast dryer through which air was circulated. The pellets were injection-molded at 280° C. using an injection molding machine provided with a die that can produce a sheet having dimensions of 100×150×3 mm to obtain a transparent resin sheet. The thickness of the sheet was 3±0.02 mm. The volatile content was 0.5%. The surface roughness (Ra) of the molded product was 1 μm. Surface defects (e.g., foreign matter, dent, projection, and scratches) were not observed with the naked eye when applying light.

### Example 1

### Surface Modification

The resin film obtained in Production Example 1 was subjected to the following ultraviolet irradiation treatment (surface modification treatment). The resin layer was immersed (cleaned) in an NaOH aqueous solution (50 g/l) at 50° C. for 2 minutes before the surface modification treatment.

### <Ultraviolet Irradiation Treatment>

High-power low-pressure mercury lamp: “PL16-110” manufactured by Sen Lights, Co., Ltd., dominant wavelength: 184.9 nm and 253.7 nm
Measurement of intensity of ultraviolet rays: “C6080-02” manufactured by Hamamatsu Photonics K.K., 9.0 mW/cm² (184.9 nm), 63 mW/cm² (253.7 nm)
Distance between mercury lamp and specimen: 30 mm
Irradiation time: 5 minutes

### Atmosphere: air

Surface temperature of resin layer: 50° C.

The resin film was washed with water after completion of each step.

In order to confirm the surface modification state, a water drop was dropped onto the surface of the specimen, and the contact angle was observed to determine the hydrophilicity of the surface of the specimen. It was confirmed by infrared absorption spectrum measurement that an —OH group and a —C═O group were formed on the surface of the resin film to which ultraviolet rays were applied.

### <Formation of Metal Layer>

A copper film (metal layer) was formed on the surface-modified melt-extruded film by plating. Table 1 shows the flow of formation of the copper film.

TABLE 1

| Step | Conditions |
|---|---|
| Preparation of specimen | |
| No washing with water | |
| Alkaline cleaning | 45° C. × 1 min |
| Washing with water | |
| Conditioning | 45° C. × 5 min |
| Washing with water | |
| Pre-dipping | 45° C. × 2 min |
| No washing with water | |
| Catalyst treatment | 45° C. × 10 min |
| Washing with water | |
| Activation | 45° C. × 3 min |
| Washing with water | |
| Electroless copper plating | 60° C. × 15 min |
| Washing with water | |
| Heating | 120° C. × 60 min |
| No washing with water | |
| Electrolysis copper plating | 25° C. × 35 min |
| Washing with water | |
| Heating | 120° C. × 60 min |

The surface-modified resin layer was immersed (cleaned) in an NaOH aqueous solution (50 g/l) at 45° C. for 1 minute (alkaline cleaning). The resin layer was then immersed in a conditioner aqueous solution (“CLEANER-CONDITIONER 231” manufactured by Rohm and Haas) at 45° C. for 5 minutes (conditioning treatment). The resin layer was then immersed in a pre-dipping aqueous solution (“CATAPREP 404 PREDIP” manufactured by Rohm and Haas) at 45° C. for 2 minutes (pre-dipping treatment). The resin layer was then immersed in a palladium chloride acidic aqueous solution at 45° C. for 10 minutes so that a plating catalyst was applied to the resin layer. After activating the plating catalyst by immersing the resin layer in a hypophosphorous acid aqueous solution at 45° C. for 3 minutes, an electroless copper plating thin film having a thickness of 0.5 μm was formed by electroless plating using a hypophosphorous acid bath. Table 2 shows the composition of the bath and the treatment conditions.

TABLE 2
Hypophosphorous acid bath
Composition

| | |
|---|---|
| CuSO₄•5H₂O | 10 g/dm³ |
| NiSO₄•6H₂O | 1 g/dm³ |
| Sodium citrate | 15 g/dm³ |
| NaPH₂O₂/H₂O | 20 g/dm³ |
| PEG-1000 | 10 g/dm³ |
| Boric acid | 15 g/dm³ |
| pH | 9.0 |
| Temperature | 60° C. |
| Stirring | |

An electrolytic copper film having a thickness of 20 μm was then formed on the copper thin film using a sulfuric acid copper plating solution having a composition shown in Table 3 (solution temperature: 25° C., current density: 3.33 A/dm²) to obtain a laminate.

TABLE 3
Composition of bath

| | | |
|---|---|---|
| CuSO₄•5H₂O | 200 | g/dm₃ |
| H₂SO₄ | 50 | g/dm₃ |
| HCl | 0.06 | g/dm₃ |
| UBAC-Ep | 0.005 | g/dm₃ |

| | |
|---|---|
| Stirring | Air blowing |

### Example 2 and Comparative Example 1

A laminate was obtained in the same manner as in Example 1, except for using the resin film obtained in Production Example 2 or the resin sheet obtained in Comparative Production Example 1.

### <Evaluation of Adhesion>

The adhesion of copper plating of the laminate was evaluated as follows. Specifically, a copper wire was formed to evaluate the utility as a material used to form a printed wiring board, and the peel strength was measured. The peel strength was 12 N/cm when using the laminate produced in Example 1 using the melt-extruded film, and was 8 N/cm when using the laminate produced in Example 2 using the melt-extruded film.

The peel strength was 5 N/cm or less when using the laminate produced in Comparative Example 1.

The surface of the copper plating layer of the laminate produced using the melt-extruded film was observed with the naked eye or using a microscope after measuring the peel strength. Almost no adhesion of the resin to the copper plating layer was observed. Specifically, the adhesive strength is normally maintained by cohesive failure of the resin layer. However, it was found that the melt-extruded film exhibited excellent adhesion to the copper plating layer even if cohesive failure did not occur. Since copper and the resin were chemically or physically bonded strongly together at a nano level, and the surface area of the resin layer had high mechanical strength, high adhesion was implemented even if the resin layer had a flat surface.

When using the laminate produced using the injection-molded sheet, adhesion of an organic substance considered to be derived from the resin to the copper plating layer was observed after measuring the peel strength. Specifically, the resin layer and the copper plating layer were strongly bonded at the interface therebetween. However, since the surface layer of the resin layer had low mechanical strength, cohesive failure occurred in the surface layer of the resin layer, so that the peel strength decreased.

### Examples 3 and 4 and Comparative Example 2

### Circuit Patterning Capability by Subtractive Process

A wiring pattern was formed on the laminate obtained in Example 1 or 2 or Comparative Example 1 by exposure and development using photolithography utilizing a UV exposure system, a photomask, and a dry film resist. The wiring pattern was then etched using a ferric chloride aqueous solution to form fifty wires (wire width: 30 μm, distance between wires: 30 μm, wire length: 50 mm) (twenty-five wires were arranged in parallel in two rows) on the laminate substrate (400×400 mm). A case where the fifty wires had a uniform shape was evaluated as “A”, a case where the wires did not have a uniform shape, but no defect was observed was evaluated as “B”, and a case where a defect was observed was evaluated as “C”. The insulating properties were determined by applying a voltage of 10 V between the electrodes. The results are shown in Table 4. The circuit pattern formed by patterning the laminate produced using the injection-molded sheet had defects (e.g., delamination). On the other hand, no defects were observed in the laminate produced using the melt-extruded film.

TABLE 4
Results for circuit patterning by subtractive process

| Resin layer | Appearance | Insulating properties |
|---|---|---|
| Production Example 1 | A | No problem |
| Production Example 2 | A | No problem |
| Comparative Production | B | Short circuit |
| Example 1 | | (defective area) |

### Examples 5 and 6 and Comparative Example 3

### Evaluation of Heat-Humidity Resistance Reliability of Substrate Provided with Copper Wiring Pattern

Comb-shaped wires (wire width: 50 μm, distance between wires: 50 μm) were formed on the laminate obtained in Example 1 or 2 or Comparative Example 1 by photolithography utilizing a UV exposure system, a photomask, and a dry film resist. A polyethylene terephthalate film was stacked on the side of the laminate on which the wires were formed to obtain an electronic circuit board. The electronic circuit board was held at 85° C. and 85% Rh (relative humidity: 85%) for 1000 hours while applying a voltage of 25 V through insulated terminals to measure the insulation resistance. When using the circuit pattern formed by patterning the laminate produced using the injection-molded sheet, conduction due to delamination occurred in one of 100 samples when 950 hours had elapsed. However, conduction due to delamination was not observed in the laminate produced using the melt-extruded film

### Example 7

### Measurement of Conductivity of Copper Plating Layer Around Copper-Resin Interface

A laminate was obtained in the same manner as in Example 2, except for changing the thickness of the electrolytic copper film to 10 μm by adjusting the electrolytic plating time. The conductivity of the copper plating layer of the resulting laminate around the copper-resin interface was measured using an MIC dielectric cylinder resonator (manufactured by Samtec) (frequency of current: 12 GHz). The conductivity relative to pure copper was 80%. As a comparison, a commercially available FR-4 substrate was subjected to the above measurement. The conductivity relative to pure copper was 50% or less.

### Examples 8 and 9 and Comparative Example 4

### Direct Circuit Patterning Capability by Selection Modification

The wiring pattern area of the resin film obtained in Production Example 1 or 2 or the resin sheet obtained in Comparative Production Example 1 was modified by photolithography utilizing a UV exposure system and a photomask. The modified area was selectively copper-plated as described above to form fifty wires (wire width: 30 μm, distance between wires: 30 μm, wire length: 50 mm) (twenty-five wires were arranged in parallel in two rows) on the laminate substrate (400×400 mm). A case where the fifty wires had a uniform shape was evaluated as “A”, a case where the wires did not have a uniform shape, but no defect was observed was evaluated as “B”, and a case where a defect was observed was evaluated as “C”. The insulating properties were determined by applying a voltage of 10 V between the electrodes. The results are shown in Table 5.

The circuit pattern formed by patterning the laminate produced using the injection-molded sheet had defects (e.g., delamination). However, no defects were observed in the laminate produced using the melt-extruded film.

TABLE 5
Results for direct circuit patterning by selective modification

| Resin layer | Appearance | Insulating properties |
|---|---|---|
| Production Example 1 | A | No problem |
| Production Example 2 | A | No problem |
| Comparative Production | B | Short circuit |
| Example 1 | | (defective area) |

### Example 10

### Transparent Conductive Film Substrate

A mesh pattern (grid pitch: 200 μm, conductor width: 20 μm, and conductor thickness: 5 μm) was formed on the resin film obtained in Production Example 2 in the same manner as in Example 9. The sheet resistance of the resuting pattern was 0.1 mΩ/square or less. The substrate was sufficiently transparent. The visible light transmittance (wavelength: 780 nm) of the laminate on which the mesh pattern was fanned was 80% relative to that of the resin layer on which wires were not formed.

### Examples 11 and 12 and Comparative Example 5

### Evaluation of Thermal Impact Reliability of Substrate Provided with Copper Wiring Pattern

A laminate in which the metal layer was formed on each side of the resin layer was obtained in the same manner as in Examples 1 and 2 and Comparative Example 1, except for performing the ultraviolet surface treatment on each side of the resin film or the resin sheet, and changing the thickness of the electrolytic copper film to 10 μm by adjusting the electrolytic plating time.

Through-holes were linearly formed in the copper-plated laminate at equal intervals of 10 mm, and the wall of the holes was plated in the same manner as the surface of the resin. Wires were alternately formed in the holes and on either side of the substrate by the subtractive process to obtain a substrate shown in FIG. 2. The resulting substrate was subjected to a test in which a thermal cycle (−40° C.: 30 min, 85° C.: 30 min (1 hour in total)) was repeated 1000 times. The resistance of the wires was measured after the test.

When using the circuit pattern formed by patterning the laminate produced using the injection-molded sheet, an increase in resistance due to disconnection was observed in one of the 1000 holes. However, an increase in resistance was not observed in the laminate produced using the melt-extruded film.

A strip-shaped copper plating layer (width: 10 mm, length: 100 mm) was formed on each side of the copper-plated laminate by the subtractive process to obtain a substrate. The resulting substrate was subjected to a test in which a thermal cycle (−40° C.: 30 min, 85° C.: 30 min (1 hour in total)) was repeated 1000 times. The peel strength of the strip-shaped copper plating layer of the laminate produced using the injection-molded sheet was 3 to 5 N/cm. The peel strength of part of the copper plating layer decreased by about 2 N/cm as compared with the peel strength before evaluation. On the other hand, the entire copper plating layer of the laminate produced using the melt-extruded film had a peel strength of 10 N/cm or more.

1. A laminate comprising a resin layer and a metal layer, the resin layer being obtained by modifying at least part of the surface of a resin film including a thermoplastic cyclic olefin resin by ionizing irradiation, and the metal layer being formed on the modified area of the surface of the resin film by plating.

2. The laminate according to claim 1, wherein the resin film has been obtained by molding the thermoplastic cyclic olefin resin by melt extrusion or melt pressing.

3. The laminate according to claim 1 or 2, wherein the resin film has a volatile content of 0.3 wt % or less.

4. The laminate according to claim 1, wherein the surface of the resin film has an arithmetic average roughness (Ra) of 1 μm or less.

5. A method of producing a laminate comprising molding a thermoplastic cyclic olefin resin by melt extrusion or melt pressing to obtain a resin film, modifying at least part of the surface of the resin film by ionizing irradiation, and forming a metal layer on the modified area of the surface of the resin film by plating.

6. The method according to claim 5, wherein the modifying of at least part of the surface of the resin film includes washing the surface of the resin layer with an alkaline aqueous solution after ionizing irradiation.

7. The method according to claim 6, wherein the forming of the metal layer includes forming a thin metal film layer by electroless plating.

8. The method according to claim 7, wherein a metal salt is used as a plating catalyst for the electroless plating.

9. The method according to claim 7 or 8, wherein a plating catalyst is adsorbed during the electroless plating by immersing the modified resin film in an aqueous solution of the plating catalyst.

10. An electronic circuit board comprising a circuit formed by etching the metal layer of the laminate according to claim 1 by photolithography.

11. An electronic circuit board comprising a circuit formed by the metal layer of the laminate according to claim 1, the resin layer being obtained by modifying a given area of the surface of the resin film including the thermoplastic cyclic olefin resin in a pattern by ionizing irradiation, and the metal layer being formed on the modified area of the surface of the resin film by plating.

12. The electronic circuit board according to claim 10 or 11, the electronic circuit board being a conductive substrate in which the circuit is formed parallel or in a mesh shape.
